(19) United States
(12) Patent Application Publication
(10) Pub. No.: US 2012/0315758 A1
(43) Pub. Date: Dec. 13, 2012

(54) SEMICONDUCTOR DEVICE MANUFACTURING METHOD

(76) Inventors: Noriko SAKURAI, Yokohama-shi (JP); Mitsuhiro Omura, Kawasaki-shi (JP); Toshiyuki Sasaki, Yokohama-shi (JP); Itsuko Sakai, Yokohama-shi (JP)

(21) Appl. No.: 13/426,513

(22) Filed: Mar. 21, 2012

(30) Foreign Application Priority Data
Jun. 7, 2011 (JP) 2011-127487

(51) Int. Cl. H01L 21/768; H01L 21/3065

(52) U.S. Cl. 438/667; 438/712; 257/E21.585; 257/E21.218

(57) ABSTRACT

According to one embodiment, a semiconductor device manufacturing method comprises mounting a supporting substrate on a front surface side of a silicon substrate having an interconnection layer and function elements formed on a front surface side, polishing a back surface side of the silicon substrate, forming a mask having an opening and an opening for a dummy hole having a diameter smaller than that of the above opening on the back surface side of the silicon substrate, etching portions exposed to the openings of the mask from the back surface side of the silicon substrate to form a via hole that reaches a part of the interconnection layer and form a dummy hole to an intermediate portion of the silicon substrate, and forming an interconnection material in the via hole.

### CROSS-REFERENCE TO RELATED APPLICATIONS

This application is based upon and claims the benefit of priority from prior Japanese Patent Application No. 2011-127487, filed Jun. 7, 2011, the entire contents of which are incorporated herein by reference.

### FIELD

Embodiments described herein relate generally to a semiconductor device manufacturing method.

### BACKGROUND

Recently, attention is paid to a 3-dimensional mounting technique used for forming interconnections by use of silicon substrate penetration electrodes in order to enhance the integration density of a semiconductor device. With this technique, after polishing the back surface side of a silicon substrate having elements formed on the front surface side thereof, via holes (through-silicon via [TSV]) that penetrate the substrate are formed by etching the substrate from the back surface side by reactive ion etching (RIE). In this case, in the condition used in RIE, gas having the high ratio of F is used as reactive gas to achieve a high etching rate. Then, after an insulating film is formed on the sidewall of the via hole by chemical vapor deposition (CVD), an interconnection metal is embedded and formed in the via hole. As formation of the interconnection metal, Cu is plated after forming a Cu seed layer by sputtering.

However, in this type of method, the following problem occurs. That is, since the silicon substrate is subjected to the polishing process, the thickness thereof varies. In order to absorb the variation, it is necessary to perform sufficient over-etching in the RIE process. Therefore, a notch is formed in the bottom portion of the via hole by excessive over-etching in the via hole arranged in a portion in which the thickness of the silicon substrate is small.

If a notch is present in the bottom portion of the via hole, the coverage of a CVD insulating film and a Cu seed layer in the notch portion becomes worse. If the coverage of the CVD insulating film becomes worse, it becomes impossible to achieve sufficient insulation. If the coverage of the Cu seed layer becomes worse, plating becomes insufficient and it may cause voids and film separation to occur.

As the mechanism of notch generation related to RIE of via hole processing, insufficient sidewall protection caused by reducing an amount of a reaction product of Si and halogen gas as represented by F and Br when etching reaches an insulating film that is an etching stop layer is considered. If sufficient sidewall protection is not attained in the bottom portion of the via hole, excessive over-etching occurs. Then, etching of the bottom portion of the via hole proceeds in a lateral direction because of the presence of a radical and, as a result, formation of a notch is considered.

In the RIE process, it is necessary for the via hole to penetrate the silicon substrate without fail. When the thickness variation of the substrate after polishing is considered, it is not practical to reduce an over-etching amount for safely acquiring a margin. Therefore, it is difficult to practically suppress formation of the notch in the bottom portion of the via hole.

### BRIEF DESCRIPTION OF THE DRAWINGS

FIGS. 1A to 1G are cross-sectional views showing manufacturing steps of a semiconductor device according to a first embodiment.

FIGS. 2A to 2C are cross-sectional views for illustrating a notch generation mechanism.

FIG. 3 is a characteristic diagram showing the relationship between the diameter of a via hole and the etching depth.

FIGS. 4A to 4D are cross-sectional views showing manufacturing steps of a semiconductor device according to a second embodiment.

FIGS. 5A to 5D are cross-sectional views showing manufacturing steps of an ion injection layer of B in the second embodiment.

### DETAILED DESCRIPTION

In general, according to one embodiment, a semiconductor device manufacturing method comprises mounting a supporting substrate on a front surface side of a silicon substrate having an interconnection layer and function elements formed on a front surface side and having an etching stop layer formed below the interconnection layer, polishing a back surface side of the silicon substrate to reduce thickness of the silicon substrate, forming a mask having an opening for a via hole for formation of a penetration electrode that contacts a portion of the interconnection layer and an opening for a dummy hole having a diameter smaller than that of the above opening on the back surface side of the silicon substrate, etching portions exposed to the openings of the mask from the back surface side of the silicon substrate to form a via hole that reaches a part of the interconnection layer and form a dummy hole to an intermediate portion of the silicon substrate, forming an insulating film on a side surface of the via hole, and forming an interconnection material in the via hole having the insulating film formed therein.

Embodiments are explained below with reference to the drawings.

### First Embodiment

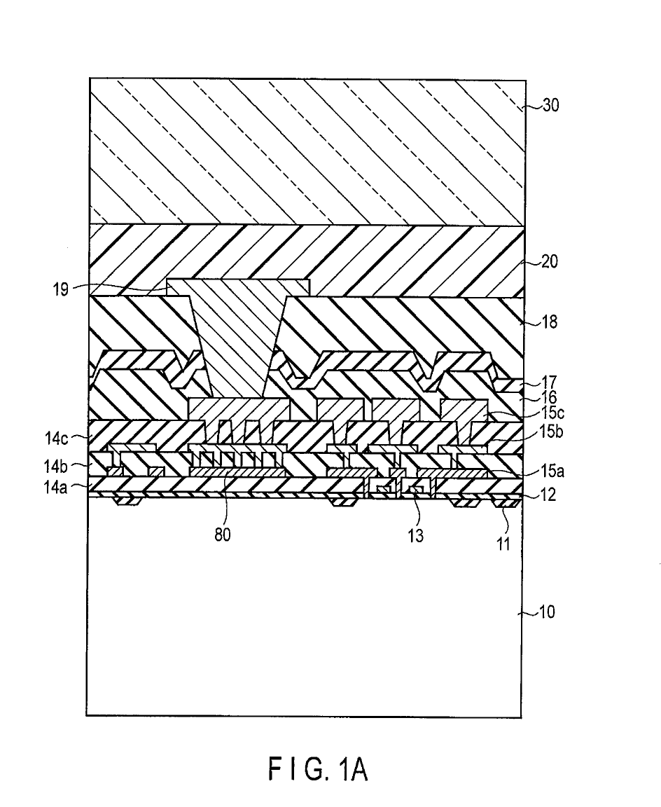

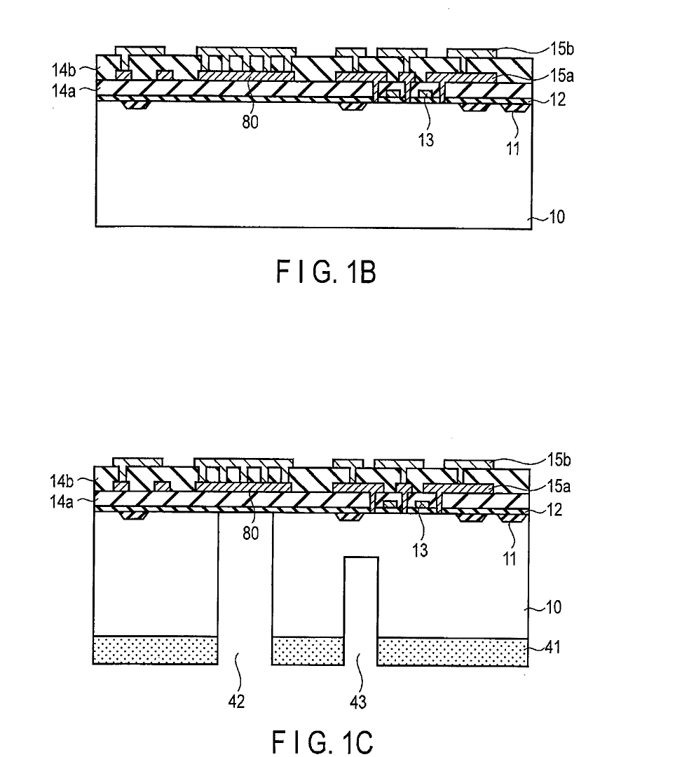

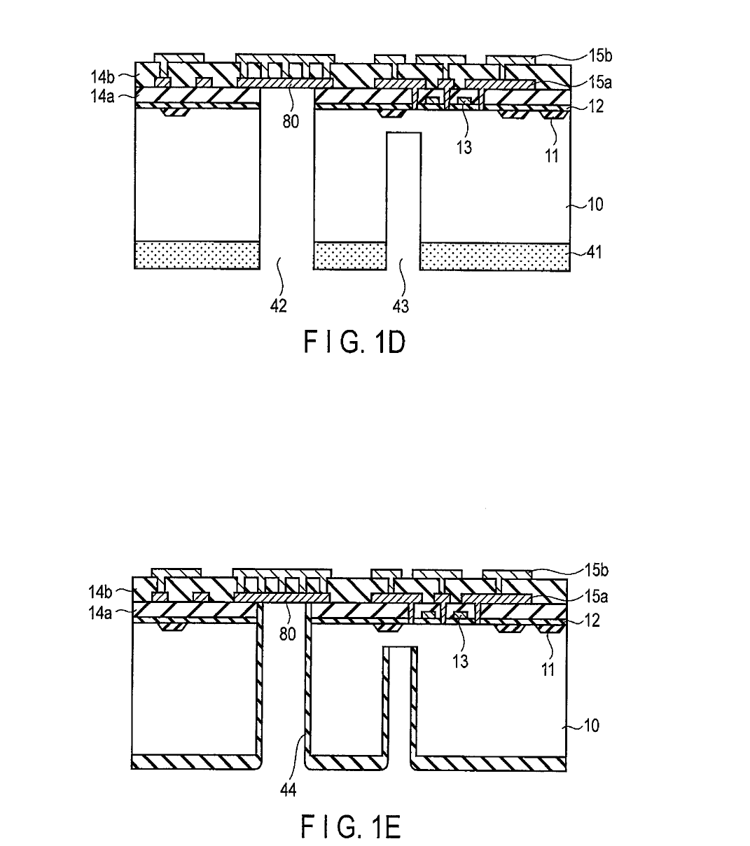

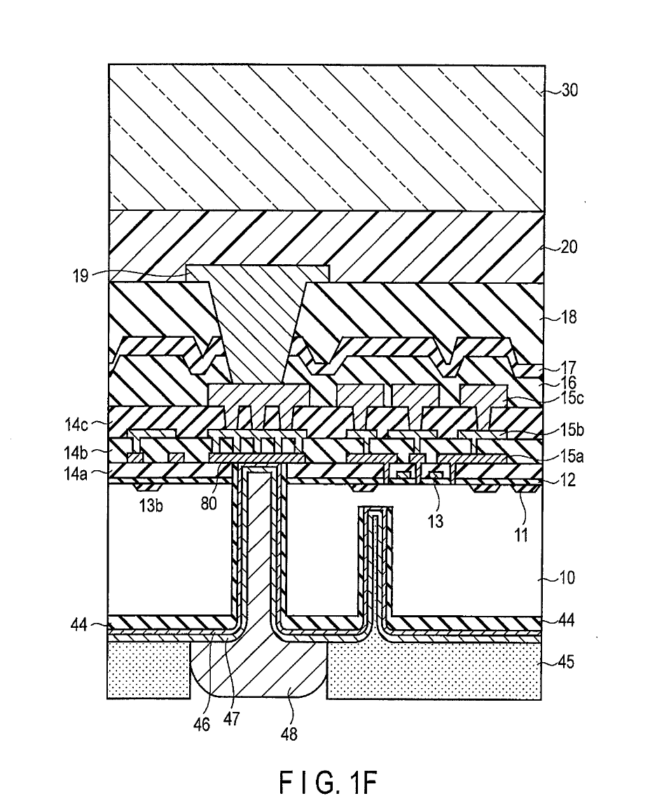

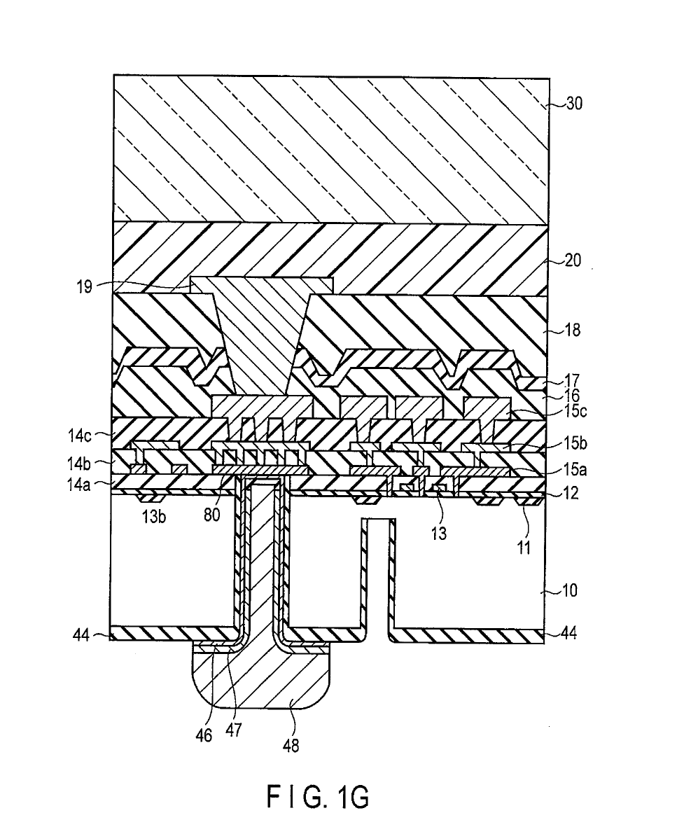

FIGS. 1A to 1G are cross-sectional views showing the manufacturing steps of a semiconductor device according to a first embodiment. In FIGS. 1B to 1E, the upper layers lying above an interconnection layer are omitted.

First, as shown in FIG. 1A, a silicon substrate 10 having an interconnection layer and function elements such as MOSFETs formed on the front surface side is used and the front surface side of the substrate 10 is bonded to a supporting substrate 30 formed of glass or the like via a bonding agent 20.

In this case, 11 in the drawing indicates a shallow trench isolation (STI) region for element isolation, 12 a gate insulating film formed of a thermal oxide film or the like, 13 a gate electrode formed of poly-Si or the like, 14a, 14b, 14c inter-level insulating films formed of silicon oxide films or the like, 15a, 15b, 15c interconnection layers formed of Cu, Al or the like, 16 a protection insulating film such as TEOS, 17 an intermediate insulating film formed of SiN, 18 a flattening insulating film formed of polyimide or the like, 19 a surface bump and 80 a connection electrode.

The STI region 11 is formed of a CVD oxide film or the like. The gate electrodes 13 are formed above the substrate 10 with the gate insulating film 12 disposed therebetween. Further, source/drain regions (not shown) are formed in the surface portion of the substrate 10 on both sides of each gate electrode 13 to form a MOSFET.

The first interconnection layers 15a are formed on the first inter-level insulating film 14a and connected to the respective source/drain regions in the substrate 10. A portion of the interconnection layer 15a that is positioned in a region in which a via hole is formed functions as the connection electrode 80.

The second interconnection layers 15b are formed on the second inter-level insulating film 14b and connected to the respective first interconnection layers 15a. The third interconnection layers 15c are formed on the third inter-level insulating film 14c and connected to the respective second interconnection layers 15b. The insulating films 16, 17, 18 are formed on the third interconnection layers 15c and third inter-level insulating film 14c. Contact holes are formed in the insulating films 16, 17, 18 and the surface bump 19 formed of Cu or the like is formed to fill the contact holes.

Although not shown in the drawing, the interconnection layers 15a, 15b, 15c may be provided via barrier layers formed of TiN or the like. Further, a function element formed on the front surface side of the substrate 10 may be a solid-state imaging device such as a CMOS sensor or CCD sensor or a semiconductor memory. In the case of the solid-state imaging sensor, interconnection can be made from the back surface side of the substrate by use of the surface bump. In the case of the semiconductor memory, a plurality of memories can be stacked to increase the storage capacity by utilizing substrate penetration electrodes formed in via holes.

Thus, the function element formed on the substrate front surface side is not limited at all and various elements can be used. Further, the manufacturing process for the interconnection layers and function elements formed on the substrate front surface side is not limited at all.

Next, as shown in FIG. 1B, the back surface side of the silicon substrate 10 is polished to reduce the thickness thereof to several 10 μm. Specifically, after polishing the back surface of the substrate 10 by means of a grinder or the like, for example, polishing is made by CMP for finishing.

Next, as shown in FIG. 1C, a mask for RIE is formed on the back surface side of the silicon substrate 10. Specifically, after forming a resist 41 on the back surface side of the silicon substrate 10, an opening for a via hole and an opening for a dummy hole whose diameter is smaller than that of the above opening are formed by a lithography technique. The opening for the via hole is provided in a position corresponding to the connection electrode 80. A via hole 42 and dummy hole 43 are formed by selectively etching the substrate 10 by RIE by use of the resist 41. At this time, the gate insulating film 12 or inter-level insulating film 14a in the via hole portion is used as an etching stop layer and over-etching is performed until the gate insulating film 12 or inter-level insulating film 14a is completely exposed in the via hole portion. This is because a plurality of via holes 42 are formed and over-etching becomes necessary by taking a variation into consideration. Since the diameter of the dummy hole 43 is small, the etching rate is low and the etching depth ends at the intermediate portion of the substrate 10 even if over-etching is performed in the portion of the via hole 42.

As reactive gas used for RIE, a gaseous mixture of SF₆, O₂, HBr or the like may be used to attain a sufficiently high selective ratio of Si with respect to the silicon oxide films of the gate insulating film 12 and inter-level insulating film 14a.

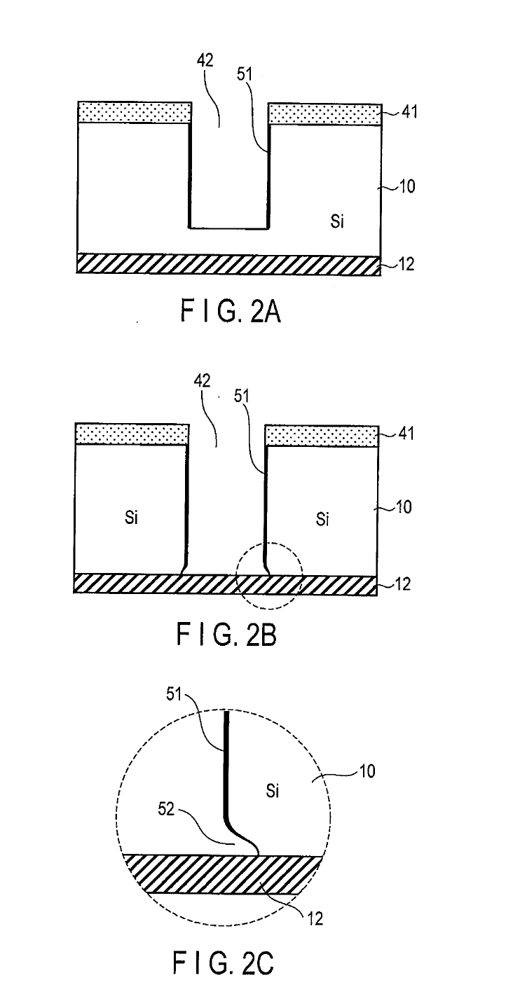

Next, a problem related to RIE for formation of via holes is explained with reference to FIGS. 2A to 2C.

In the case of an etching process using the above reactive gas, as shown in FIG. 2A, Si is anisotropically etched. At this time, SiF₄, SiBr₄ or the like is formed by etching Si and the thus created substance and the oxide thereof are attached to the etching sidewall. That is, a protection film 51 formed of the attachment is formed on the sidewall of the via hole 42 at the same time of progress of etching. As a result, the sidewall of the via hole 42 can be prevented from being etched by radicals and the etching process is performed only in the depth direction.

If the etching process progresses and reaches the gate insulating film 12 or inter-level insulating film 14a formed of silicon oxide films as shown in FIG. 2B, SiF₄, SiBr₄ or the like is not formed because Si is not consumed. If over-etching is further performed in this state, as shown in FIG. 2C that shows the enlarged view of FIG. 2B, the protection film 51 of the sidewall is not formed. Therefore, etching in the via hole bottom portion by radicals proceeds in the lateral direction and a notch 52 is formed in the bottom portion of the via hole 42.

If such a notch 52 is formed, the coverage of a CVD oxide film 44 or Cu seed layer 46 used for sidewall protection as will be described later becomes worse and sufficiently high insulation cannot be realized or plating becomes insufficient. Further, no film is formed on a portion of the notch 52 and a so-called “void” may be formed.

On the other hand, in this embodiment, etching of

Si proceeds in the dummy hole portion during over-etching of the via hole portion. Therefore, SiF₄, SiBr₄ or the like that is a reactive product of halogen-series gas and Si and the oxide thereof are formed and the thus created substance is attached to the sidewall of the via hole portion. Therefore, even if etching is continuously performed even after the via hole 42 reaches the gate insulating film 12 or inter-level insulating film 14a, the sidewall of the via hole 42 can be protected from being influenced by radicals. As a result, formation of the notch 52 can be suppressed.

In Si etching, a so-called p-loading effect that the etching rate becomes lower as the hole diameter becomes smaller (the aspect ratio becomes larger) is provided. Since the opening diameter of the dummy hole 43 is formed smaller than that of original via hole 42, the etching rate thereof becomes low because of the μ-loading effect. As shown in FIG. 10, the via hole 42 and dummy hole 43 are simultaneously processed. Therefore, even if the original via hole 42 reaches the gate insulating film 12 or inter-level insulating film 14a, the dummy hole 43 with a small hole diameter does not penetrate the silicon substrate 10 and continuously supplies a reactive product of halogen-series gas and silicon. As a result, a reactive product of a halogen-series gas and silicon is also supplied to the original via hole 42. Therefore, the sidewall of the bottom portion of the original via hole 42 is protected and generation of notches because of excessive over-etching can be suppressed.

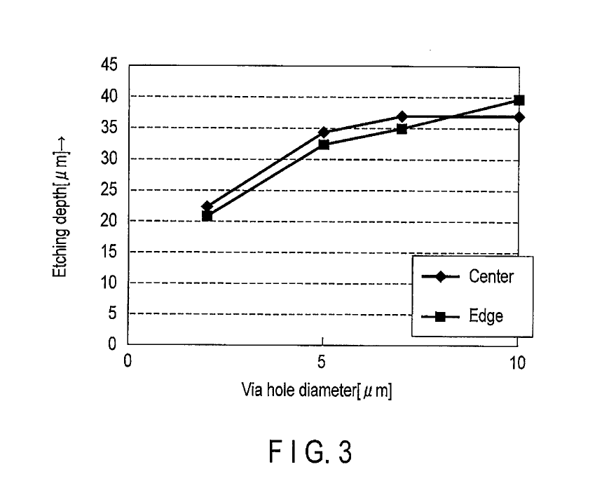

FIG. 3 is a characteristic diagram showing the relationship between the diameter of the via hole 42 and the etching depth. There is shown a variation in the depths of a plurality of via holes having different diameters when an etching process is performed for a preset period of time by RIE using a gaseous mixture of SF₆, O₂, HBr or the like. As is understood from FIG. 3, the etching depth becomes larger as the diameter of the via hole 42 becomes larger.

As a condition for preventing the dummy hole 43 from reaching the gate insulating film 12 and inter-level insulating film 14a at the time of over-etching of the via hole 42, for example, the following calculations may be made. As the via hole 42, a penetration hole in which the diameter φ is 10 μm and the depth is 40 μm is assumed as the via hole 42 and the over-etching ratio of the via hole 42 is 20%. In this case, when etching is made by 40+8=48 μm for formation of the via hole 42, the dummy hole 43 may be formed with the depth 40 μm (36 μm or less when a variation in the thickness of Si is included). The etching rate related to the dummy hole 43 at this time becomes 36/48=¾ or less.

Further, it is supposed that the amount of a product supplied from the dummy hole 43 is determined based on the volume to be etched. In this case, if the volume of approximately 1/10 of the volume to be etched for each unit time in the original via hole 42 is etched in the dummy hole 43, it can be said that a notch suppression effect can be provided. Therefore, even if a plurality of via holes 42 are provided, it is not necessary to form dummy holes 43 corresponding in number to the via holes 42 and it is sufficient to form one dummy hole 43 or via holes 43 smaller in number than the via holes 42.

Based on the above fact, if φ 10 μm is selected as a target dimension of the via hole 42, it is preferable to set φ 4 μm or less as the diameter of the dummy hole 43 as understood from FIG. 3. However, the above condition is set by taking an excessively sufficient margin into consideration, and in practice, it is preferable to set φ 5 μm or less as the diameter of the dummy hole. That is, the diameter of the dummy hole 43 may be set to half the diameter of the via hole or less.

Next, as shown in FIG. 1D, the gate insulating film 12 and inter-level insulating film 14a exposed to the bottom portion of the via hole portion are etched. The etching process may be performed by changing the reactive gas for RIE. That is, CF₄, CHF₃ or the like that can provide a sufficiently high selective etching ratio with respect to Si may be used at the etching time for the silicon oxide film.

Next, as shown in FIG. 1E, after the resist 41 is removed, a silicon oxide film is formed by CVD and the silicon oxide film is etched back. As a result, an oxide film 44 is left behind on the hole side surface. At this time, the oxide film 44 is also left behind on the back surface of the substrate 10. That is, when an oxide film is deposited to 2.5 μm by CVD, the thickness of the oxide film on the bottom portion of the via hole 42 becomes approximately 1 μm. Then, if an etch-back process is performed to remove the oxide film on the bottom portion, the oxide film 44 is left behind on the hole side surface and the back surface of the substrate 10.

Next, as shown in FIG. 1F, a barrier layer 46 formed of TiN or the like and Cu seed layer 47 are formed by subjecting the back surface side of the substrate 10 to sputtering. Subsequently, after a resist 45 used as a mask is formed on the back surface side of the substrate 10, an opening including the via hole 42 therein is formed by lithography. Then, Cu is formed by plating to form a substrate penetration electrode 48.

Next, as shown in FIG. 1G, by removing the barrier layer 46 and Cu seed layer 47 after the resist 45 is removed, a semiconductor device is completed.

Thus, according to this embodiment, the notch 52 can be suppressed from being formed at the formation time of the via hole 42 by forming the dummy hole 43 that does not penetrate the substrate 10 together with the via hole 42 that penetrates the silicon substrate 10. As a result, the manufacturing yield can be enhanced. Further, since it is only required to form an opening for formation of the dummy hole in a mask used for formation of the via hole, the number of steps for formation of the dummy hole 43 is not increased.

### Second Embodiment

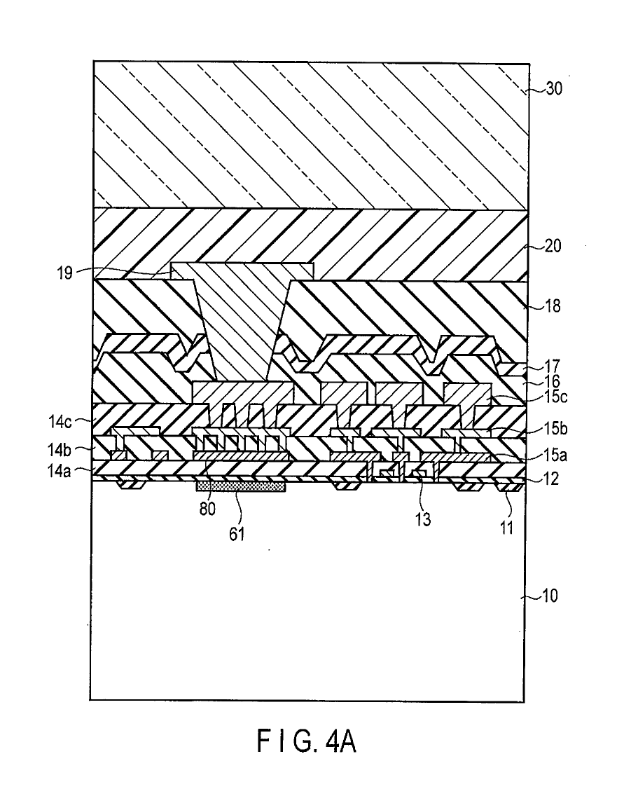

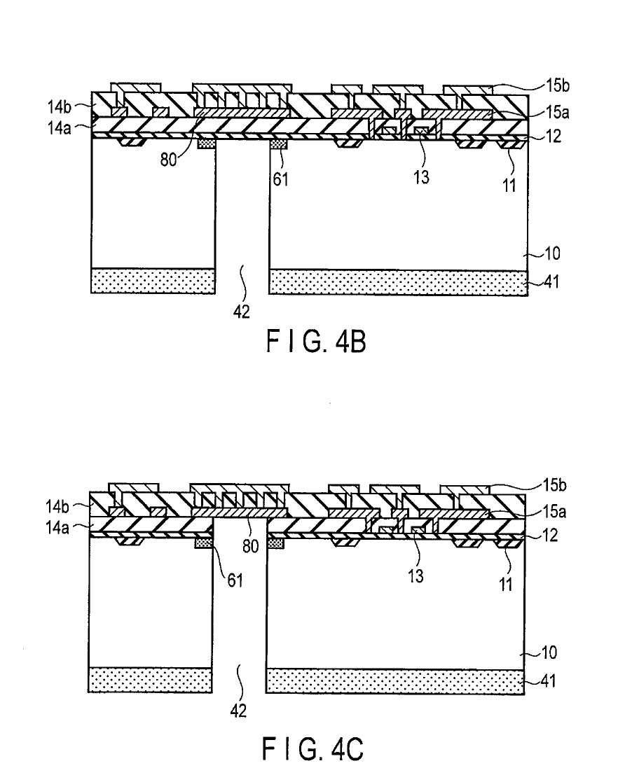

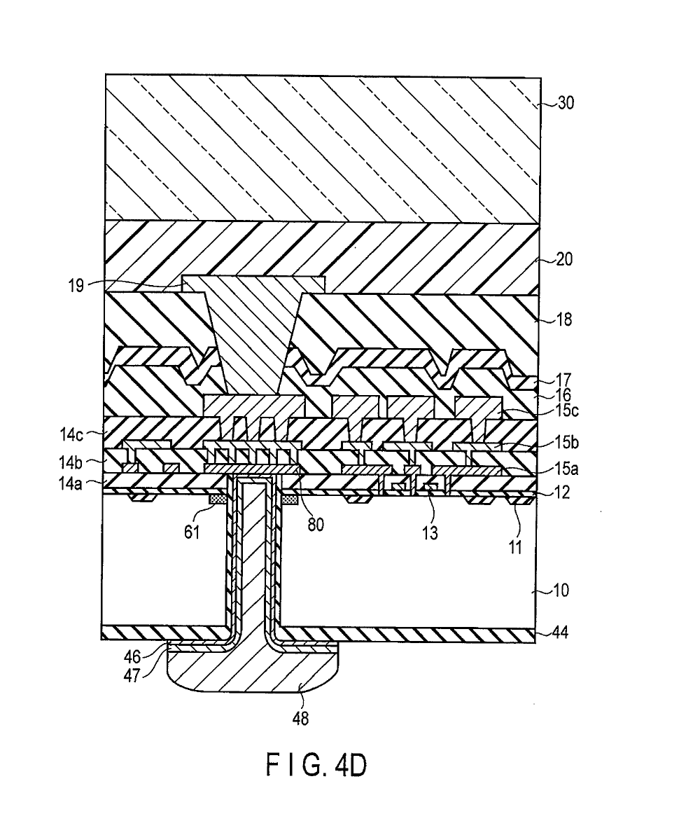

FIGS. 4A to 4D are cross-sectional views showing the manufacturing steps of a semiconductor device according to a second embodiment. In FIGS. 4B, 4C, the layers lying above the interconnection layer are omitted. Further, portions that are the same as those of FIGS. 1A to 1G are denoted by the same symbols and the detailed explanation thereof is omitted.

This embodiment is different from the first embodiment explained before in that a B-ion injection layer is previously formed in a portion lying on the bottom portion of the via hole instead of forming the dummy hole.

FIG. 4A shows a state in which the front surface side of a silicon substrate 10 having an interconnection layer and function elements such as MOSFETs or the like formed on the front surface side is bonded to a supporting substrate 30 via a bonding agent 20. This is different from FIG. 1 of the first embodiment in that a B-ion injection layer 61 is formed below the connection electrode of the via hole portion.

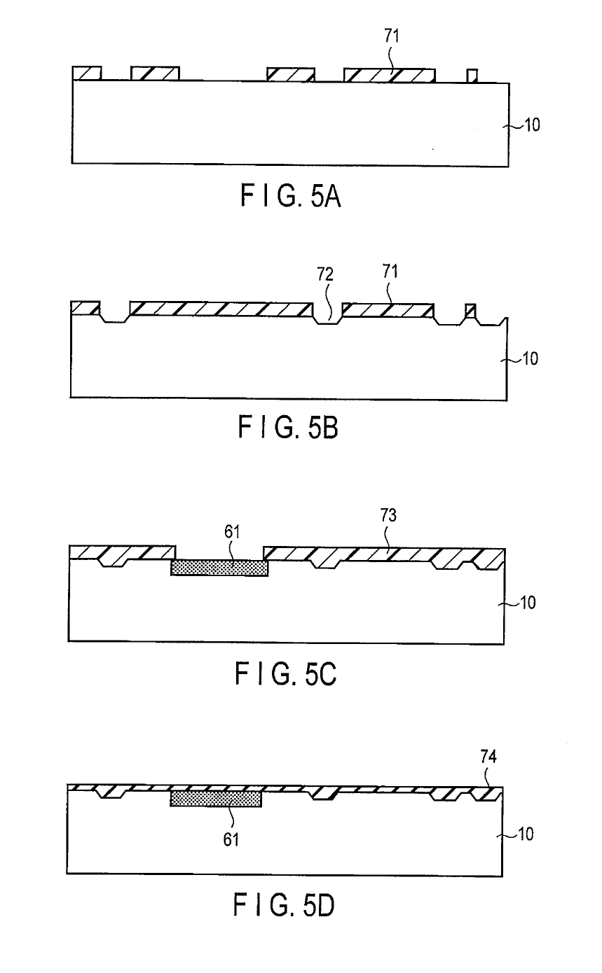

The B-ion injection layer 61 is formed according to the steps of FIGS. 5A to 5D, for example.

First, as shown in FIG. 5A, a resist 71 having an opening formed in an element isolation region is formed on the surface of the silicon substrate 10.

Next, as shown in FIG. 5B, an element isolation grove 72 is formed by selectively etching the surface side of the substrate 10 by RIE with the resist 71 used as a mask.

Subsequently, after the resist 71 is temporarily removed, a resist 73 having an opening is formed on a region in which a via hole is to be formed as shown in

FIG. 5C. In practice, the diameter of the opening of the resist 73 is set slightly larger than the diameter of the via hole by taking a positional deviation at the via hole formation time into consideration. In this state, an ion injection region 61 is formed in a region in which a via hole is to be formed by injecting B ions. The etching rate of the ion injection region 61 becomes lower in comparison with that of an Si substrate region in which ions are not injected in an RIE process as will be described later.

Next, after the resist 73 is removed, a CVD oxide film 74 is deposited to fill the element isolation groove 72 with the oxide film 74 as shown in FIG. 5D. Then, the surface thereof is etched back to leave behind the oxide film 74 only in the element isolation groove 72. As a result, an STI region 11 is formed.

The structure of FIG. 4A is obtained by bonding the front surface side of the substrate 10 to the supporting substrate 30 via the bonding agent 20 after forming MOSFETs on the substrate, forming various interconnection layers and forming surface bumps.

After this, as shown in FIG. 4B, like the first embodiment, after the back surface of the substrate 10 is polished to reduce the thickness thereof, a resist 41 having an opening for formation of a via hole is formed on the back surface of the substrate 10. Then, a via hole 42 is formed by selectively etching the substrate 10 by RIE with the resist 41 used as a mask until it reaches the gate insulating film 12 or inter-level insulating film 14a. In this case, since a plurality of via holes are provided, over-etching becomes necessary by taking a variation into consideration. Further, as reactive gas used for RIE, a gaseous mixture of SF₆, O₂, HBr or the like may be used like the former embodiment.

With the conventional method, a notch is formed at the over-etching time of the via hole 42. However, in this embodiment, formation of the notch can be suppressed because the ion injection layer 61 is formed. That is, since the ion injection layer 61 is formed on the bottom portion of the via hole 42, the etching rate becomes low when the etching reaches the ion injection layer 61. Since the etching rate becomes low in the via hole bottom portion, the of amount etching by radicals in the lateral direction becomes extremely small even if a sidewall protection film is not formed. Therefore, formation of the notch in the via hole bottom portion can be suppressed.

Next, as shown in FIG. 4C, the gate insulating film 12 and inter-level insulating film 14a exposed to the bottom portion of the via hole portion are selectively etched. The etching process may be performed by changing the reactive gas to CF₄, CHF₃ or the like for RIE.

Then, as shown in FIG. 4D, after the resist 41 is removed, an oxide film 44 is formed for via insulation like the first embodiment and a barrier layer 46 and Cu seed layer 47 are formed. Subsequently, Cu is formed by plating to form a substrate penetration electrode 48. Thus, a semiconductor device is completed.

As described above, according to this embodiment, formation of notches at the formation time of the via holes 42 can be suppressed by previously forming the B-ion injection layer 61 on the bottom portion of the via hole portion formed from the substrate back surface side. Therefore, like the first embodiment, the manufacturing yield can be enhanced and the reliability can be enhanced.

Formation of notches can be further suppressed by forming dummy holes as in the first embodiment in addition to the feature of the second embodiment that the ion injection layer is formed.

(Modification)

This invention is not limited to the above embodiments. The function element formed on the silicon substrate is not limited to a solid-state imaging device or semiconductor memory and it may be a logic element. In this case, a logic system can be configured with a small area by integrally laminating silicon substrates having different function elements formed thereon. Further, this invention can be applied to a device that requires a via hole penetrating the substrate.

In the above embodiments, a case wherein a bulk substrate is used is explained, but the embodiments are not limited to this case and can be applied to a method for manufacturing a Micro-electromechanical System (MEMS) using an SOI substrate. When the MEMS is formed on the SOI substrate, a process for forming via holes in the base portion of the SOI substrate becomes necessary and notches may be formed at this time. Even in such a case, formation of notches can be suppressed by previously forming dummy holes or ion injection layers as explained in the above embodiments.

B is injected to form an ion injection layer in the second embodiment, but injected ions are not necessarily limited to B and any ions can be used if the etching rate of a portion having the ions injected therein becomes lower than that of Si that is not ion-injected. Specifically, a Group-III element such as In can be used in addition to B.

Gas used for etching the silicon substrate is not limited to a gaseous mixture of SF₆, O₂, HBr or the like and a condition in which, for example, NF₃, Cl₂ or the like and CF₄, CHF₃, HBr or the like for shape control as additive gas are mixed may be considered. Further, gas used when the etching stop layer is etched is not limited to CF₄ and CHF₃ and, for example, C₄F₈ and C₄F₆ can be used and a condition in which CH₃F, He, Ar or the like as additive gas is mixed with the above gas can be considered.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method comprising:
mounting a supporting substrate on a front surface side of a silicon substrate having an interconnection layer and function elements formed on the front surface side thereof and having an etching stop layer formed below the interconnection layer,
polishing a back surface side of the silicon substrate mounted on the supporting substrate to reduce thickness of the silicon substrate,
forming a mask having a first opening for a via hole for formation of a penetration electrode contacting a portion of the interconnection layer and a second opening for a dummy hole having a diameter smaller than the first opening on the back surface side of the silicon substrate whose thickness is reduced,
forming a via hole reaching the portion of the interconnection layer and forming a dummy hole extending to an intermediate portion of the silicon substrate by etching portions exposed to the first and second openings of the mask from the back surface side of the silicon substrate,
forming an insulating film on side surface of the via hole, and
forming an interconnection material in the via hole having the insulating film formed therein.

2. The method of claim 1, wherein the forming the via hole and the dummy hole comprises,
selectively etching the silicon substrate by use of a reactive ion etching method using reactive gas until the etching reaches the etching stop layer in a via hole portion and then selectively etching the etching stop layer by changing the reactive gas.

3. The method of claim 2, wherein the reactive ion etching method comprises,
performing over-etching until a whole portion of the etching stop layer is exposed to the via hole portion.

4. The method of claim 3, wherein an opening diameter of the dummy hole is set to prevent the dummy hole from reaching the etching stop layer even by over-etching of the via hole.

5. The method of claim 1, wherein the etching stop layer is a gate insulating film formed of a silicon oxide film formed on a front surface portion of the silicon substrate.

6. The method of claim 1, wherein the dummy hole has an opening diameter that is not larger than half the opening diameter of the via hole for substrate penetration.

7. The method of claim 1, wherein the forming a mask comprises, forming a mask having a plurality of openings for a plurality of via holes.

8. A semiconductor device manufacturing method comprising:
mounting a supporting substrate on a front surface side of a silicon substrate having an interconnection layer and function elements formed on the front surface side thereof and having an ion injection region of a Group-III element formed in a surface region facing a portion of the interconnection layer,
polishing a back surface side of the silicon substrate mounted on the supporting substrate to reduce thickness of the silicon substrate,
forming a via hole used for formation of a penetration electrode contacting a portion of the interconnection layer by selectively etching the silicon substrate whose thickness is reduced from the back surface side of the silicon substrate in a region containing a portion of the ion injection region,
forming an insulating film on a side surface of the via hole, and
forming an interconnection material in the via hole having the insulating film formed therein.

9. The method of claim 8, wherein B is used as ions for formation of the ion injection region.

10. The method of claim 8, further comprising an etching stop layer between the ion injection region and the interconnection layer.

11. The method of claim 10, wherein the etching stop layer is a gate insulating film formed of a silicon oxide film formed on the front surface portion of the silicon substrate.

12. A semiconductor device manufacturing method comprising:
mounting a supporting substrate on a front surface side of a silicon substrate having an etching stop layer formed on at least a portion of the surface thereof, and
selectively etching the silicon substrate from the back surface side to form a first hole that reaches the etching stop layer and a second hole whose diameter is smaller than an opening of the first hole and that does not reach the etching stop layer.

13. The method of claim 12, wherein the forming the first hole and the second hole comprises,
selectively etching the silicon substrate to reach the etching stop layer in a portion of the first hole by a reactive ion etching method using reactive gas and then selectively etching the etching stop layer by changing the reactive gas is performed.

14. The method of claim 13, wherein the reactive ion etching method comprises,
performing over-etching until a whole portion of the etching stop layer is exposed to the first hole portion.

15. The method of claim 14, wherein an opening diameter of the second hole is set to prevent the second hole from reaching the etching stop layer even at the time of over-etching for the first hole.

16. The method of claim 12, wherein the second hole has an opening diameter that is not larger than half an opening diameter of the first hole.
